(19) United States
(12) Patent Application Publication
(10) Pub. No.: US 2009/0315027 A1
(43) Pub. Date: Dec. 24, 2009

(54) LIGHT EMITTING DEVICE AND MANUFACTURING METHOD OF LIGHT EMITTING DEVICE

(75) Inventors: Takashi KIDU, Tokyo (JP); Minoru Kumagai, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/486,789

(22) Filed: Jun. 18, 2009

(30) Foreign Application Priority Data
Jun. 24, 2008 (JP) 2008-163941
Jun. 24, 2008 (JP) 2008-163950

(51) Int. Cl. H01L 33/00; H01L 21/28

(52) U.S. Cl. 257/43; 438/29; 257/E33.061; 257/E21.158

(57) ABSTRACT

A manufacturing method of a light emitting device in which at least one carrier transporting layer is interposed between a first electrode and a second electrode, includes: removing a surface layer of a partition that surrounds a periphery of at least one side of the first electrode by a thickness of 50 nm or more; and forming the carrier transporting layer on the first electrode, the carrier transporting layer being in contact with the partition and containing a transition metal oxide.

### BACKGROUND OF THE INVENTION

1. Field of the Invention

The present invention relates to a light emitting device and a manufacturing method of the light emitting device.

2. Description of the Related Art

In recent years, a display device to which an electroluminescence (EL) panel in which a plurality of EL light emitting elements known as self light emitting elements are arrayed in a matrix form is applied, has been known as a display device of an electronic instrument such as a cellular phone.

In a manufacturing process of the EL panel, there is a step of depositing an EL layer by evaporation or application.

For example, JP-Tokukai-2007-134321A describes a technology for satisfactorily depositing the EL layer in such a manner that, in the case of depositing the EL layer by the application, ultraviolet irradiation treatment or plasma treatment is carried out for the EL layer in advance to achieve enhancement of wettability of an electrode surface.

However, in the EL panel manufactured by carrying out the above-described related art, it has been found out that non-light emitting portions in which the EL elements do not partially emit light, are caused among the plurality of EL elements composing a light emitting region of the EL panel. These non-light emitting portions include regions which do not partially emit the light on random spots of the EL panel, so-called dark spots, and dark areas which are non-light emitting regions generated concentratedly on a peripheral edge portion of the EL panel.

### SUMMARY OF THE INVENTION

It is an advantage of the preset invention to provide a light emitting device which is excellent in light emission characteristics, and to provide a manufacturing method of the light emitting device.

According to a first aspect of the present invention, a manufacturing method of a light emitting device in which at least one carrier transporting layer is interposed between a first electrode and a second electrode, the manufacturing method comprises:

removing a surface layer of a partition that surrounds a periphery of at least one side of the first electrode by a thickness of 50 nm or more; and

forming the carrier transporting layer on the first electrode, the carrier transporting layer being in contact with the partition and containing a transition metal oxide.

According to a second aspect of the present invention, a light emitting device comprises:

a first electrode;

a second electrode;

at least one carrier transporting layer which is interposed between the first electrode and the second electrode;

a partition for surrounding a periphery of at least one side of the first electrode,

wherein a surface layer of the partition is removed by a thickness of 50 nm or more from a thickness of the surface layer at a time when the surface layer is deposited, and

the carrier transporting layer contains a transition metal oxide, is in contact with the partition, and is formed on the first electrode.

According to the present invention, the light emitting device having excellent light emission characteristics can be realized.

It is preferable that the partition contains a polyimide resin material.

It is preferable that the transition metal oxide contains molybdenum oxide.

It is preferable that the surface layer of the partition be removed by the thickness of 50 nm to 1 μm.

It is preferable that the surface layer of the partition be removed by the thickness of 90 nm to 1 μm.

It is preferable that the surface layer of the partition is removed by plasma treatment.

It is preferable that the surface layer of the partition is removed by oxygen plasma treatment.

The light emitting device manufactured by the above manufacturing method of the light emitting device is preferable.

### BRIEF DESCRIPTION OF THE DRAWINGS

The present invention will become more fully understood from the detailed description given hereinafter and the accompanying drawings given by way of illustration only, and thus are not intended as a definition of the limits of the present invention, and wherein:

FIG. 1 is a plan view showing an arrangement configuration of pixels of an EL panel;

FIG. 2 is a plan view showing a schematic configuration of the EL panel;

FIG. 3 is a circuit diagram showing a circuit equivalent to one pixel of the EL panel;

FIG. 4 is a plan view showing one pixel of the EL panel;

FIG. 5 is an arrow cross-sectional view of a plane along a line V-V of FIG. 4;

FIG. 6 is an arrow cross-sectional view of a plane along a line VI-VI of FIG. 4;

FIG. 7 is a cross-sectional view showing a bank formed on an upper surface side of a substrate;

FIG. 8 is a cross-sectional view showing hole injection layers formed in opening portions;

FIG. 9 is a cross-sectional view showing the hole injection layers, functional layers and light emitting layers, which are formed in the opening portions;

FIG. 10 is a plan view showing an arrangement configuration of the pixels of the EL panel;

FIG. 11 is a plan view showing one pixel of the EL panel;

FIG. 12 is a plan view showing one pixel of the EL panel;

FIG. 13 is an arrow cross-sectional view of a plane along a line XIII-XIII of FIG. 12;

FIG. 14 is a plan view showing one pixel of the EL panel;

FIG. 15 is a plan view of an arrangement configuration of pixels of an EL panel for use in a light emission test;

FIG. 16 is an arrow cross-sectional view along a line XVI-XVI of FIG. 15, and is also an explanatory view showing constituents for one pixel;

FIG. 17 is an explanatory diagram showing data regarding a surface shape of a bank for which UV ozone treatment is carried out for two minutes;

FIG. 18 is an explanatory diagram showing data regarding a surface shape of the bank for which oxygen plasma treatment is carried out for five minutes;

FIG. 19 is an explanatory diagram showing data regarding a surface shape of the bank for which the oxygen plasma treatment is carried out for ten minutes;

FIG. 20A is an explanatory view showing a light emission image in the vicinity of a center of an EL panel of a comparative example, in which a surface layer of a bank is not cut away;

FIG. 20B is an explanatory view showing a light emission image in the vicinity of a center of an EL panel of a comparative example, in which a surface layer of a bank is removed by a thickness of 35 nm;

FIG. 21A is an explanatory view showing a light emission image in the vicinity of a center of an EL panel of an example, in which a surface layer of a bank is removed by a thickness of 50 nm;

FIG. 21B is an explanatory view showing a light emission image in the vicinity of a center of an EL panel of an example, in which a surface layer of a bank is removed by a thickness of 70 nm;

FIG. 22A is an explanatory view showing a light emission image of a peripheral edge region of the EL panel in which the surface layer of the bank is removed by the thickness of 50 nm;

FIG. 22B is an explanatory view showing a light emission image of a peripheral edge region of the EL panel in which the surface layer of the bank is removed by the thickness of 70 nm;

FIG. 23A is an explanatory view showing a light emission image of an EL panel in which a surface layer of a bank is removed by a thickness of 90 nm;

FIG. 23B is an explanatory view showing a light emission image of an EL panel in which a surface layer of a bank is removed by a thickness of 110 nm;

FIG. 24A is an explanatory view showing a light emission image of the entire EL panel in which the surface layer of the bank is removed by the thickness of 50 nm; and

FIG. 24B is an explanatory view showing a light emission image of the entire EL panel in which the surface layer of the bank is removed by the thickness of 110 nm.

### DETAILED DESCRIPTION OF PREFERRED EMBODIMENT

A description will be made below of a preferred embodiment for carrying out the present invention by using the drawings. Note that, though a variety of technically preferable limitations are imposed on the embodiment to be described below for the purpose of carrying out the present invention, the scope of the invention is not limited to the following embodiment and illustrated examples.

Note that, in this embodiment, a description will be made of the present invention while a light emitting device is applied to an EL panel which is a display device.

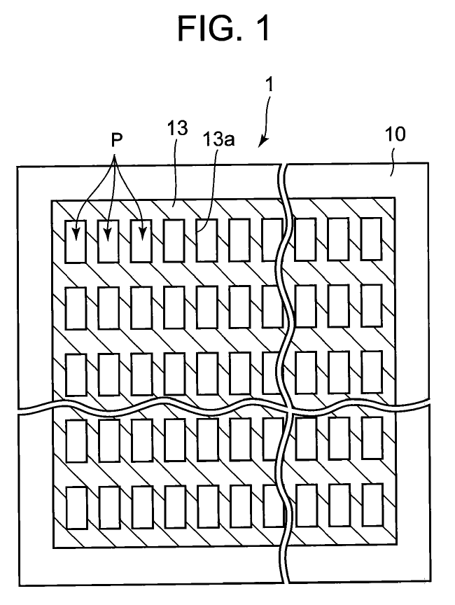

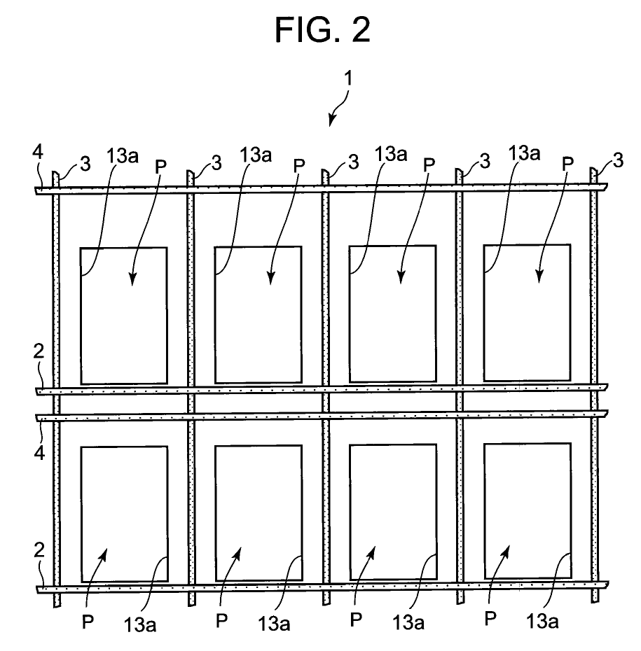

FIG. 1 is a plan view showing an arrangement configuration of a plurality of pixels P in an EL panel 1, and FIG. 2 is a plan view showing a schematic configuration of the EL panel 1.

As shown in FIG. 1 and FIG. 2, in this EL panel 1, the plurality of pixels P which individually emit, for example, light of red (R), green (G) and blue (B) are arranged in a predetermined pattern into a matrix form.

On the EL panel 1, a plurality of scan lines 2 are arrayed so as to be substantially parallel to one another along a row direction, and a plurality of signal lines 3 are arrayed so as to be substantially parallel to one another along a column direction substantially perpendicular to the scan lines 2 when viewed from the above. Moreover, among the scan lines 2 adjacent to one another, voltage supply lines 4 are provided along the scan lines 2. Then, a range surrounded by two adjacent signal lines 3, the respective scan lines 2 and the respective voltage supply lines 4 is equivalent to each of the pixels P.

Moreover, on the EL panel 1, a bank 13 which is a grid-like partition is provided so as to cover upper portions of the scan lines 2, the signal lines 3 and the voltage supply lines 4. A plurality of substantially rectangular opening portions 13a formed by being surrounded by the bank 13 are formed for each of the pixels P, and a hole injection layer 8b, a functional layer 8c and a light emitting layer 8d, which will be described later, are provided in each of the opening portions 13a.

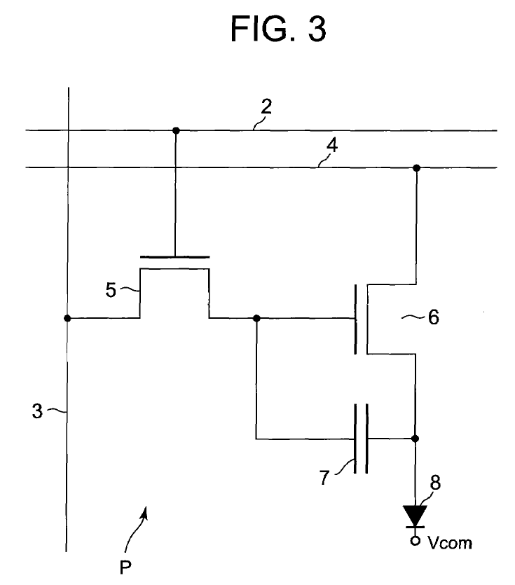

FIG. 3 is a circuit diagram showing a circuit equivalent to one pixel of the EL panel 1 that operates in accordance with an active matrix drive mode.

As shown in FIG. 3, the scan lines 2, the signal lines 3 which intersect the scan lines 2, and the voltage supply lines 4 which go along the scan lines 2 are provided in the EL panel 1. For one pixel P of this EL panel 1, a switch transistor 5 which is a thin-film transistor, a drive transistor 6 which is a thin-film transistor, a capacitor 7, and an EL element 8 are provided.

In each pixel P, a gate of the switch transistor 5 is connected to the scan line 2, one of a drain and source of the switch transistor 5 is connected to the signal line 3, and the other of the drain and source of the switch transistor S is connected to one of electrodes of the capacitor 7 and to a gate of the drive transistor 6. One of a source and drain of the drive transistor 6 is connected to the voltage supply line 4, and the other of the source and drain of the drive transistor 6 is connected to the other electrode of the capacitor 7 and to an anode of the EL element 8. Note that cathodes of the EL elements 8 of all the pixels P are maintained at a constant voltage Vcom (for example, are grounded).

Moreover, on the periphery of the EL panel 1, the respective scan lines 2 are connected to a scan driver, the respective voltage supply lines 4 are connected to a constant voltage source or a driver that outputs a voltage signal as appropriate, and the respective signal lines 3 are connected to a data driver. By these drivers, the EL panel 1 is driven in accordance with the active matrix drive mode. Predetermined power is supplied to the voltage supply lines 4 by the constant voltage source or the driver.

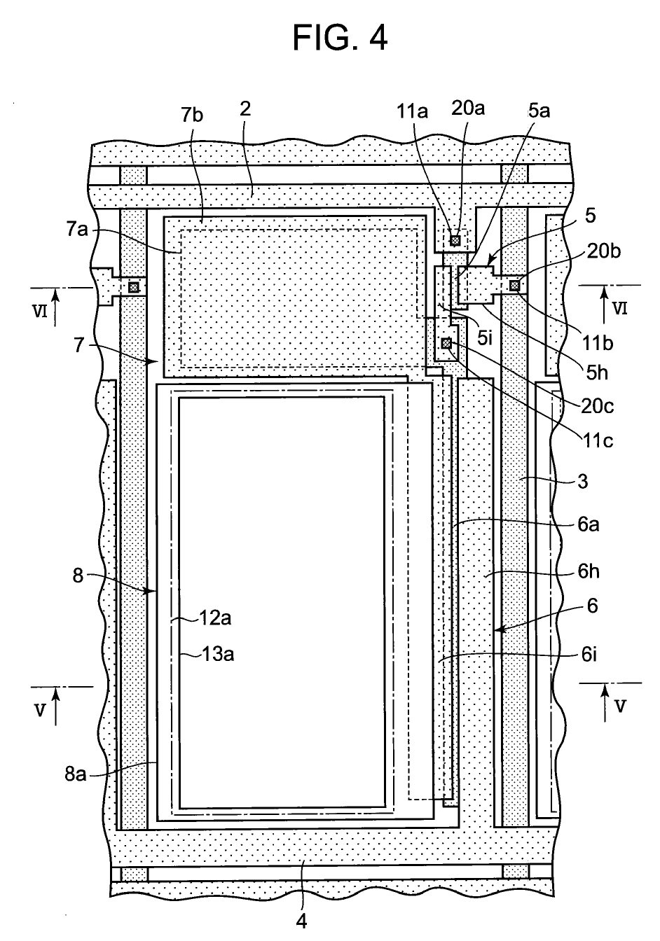

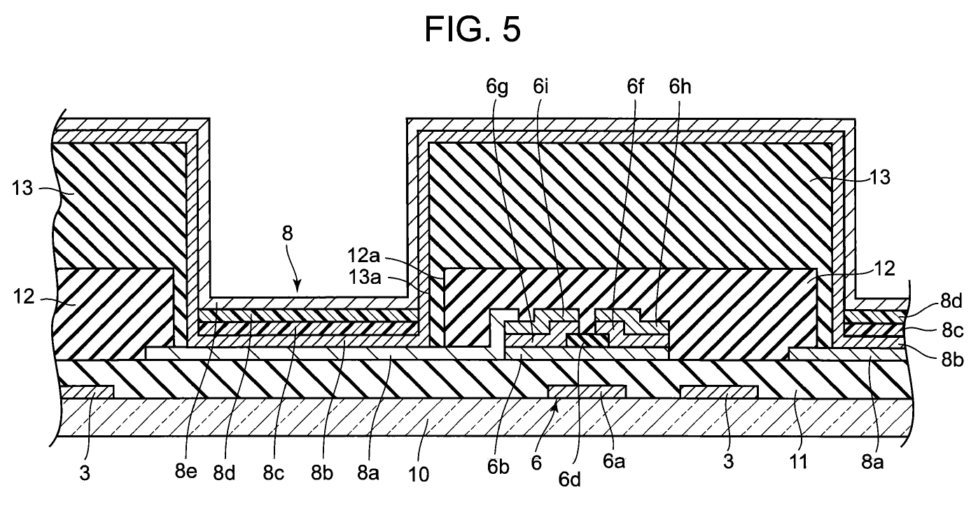

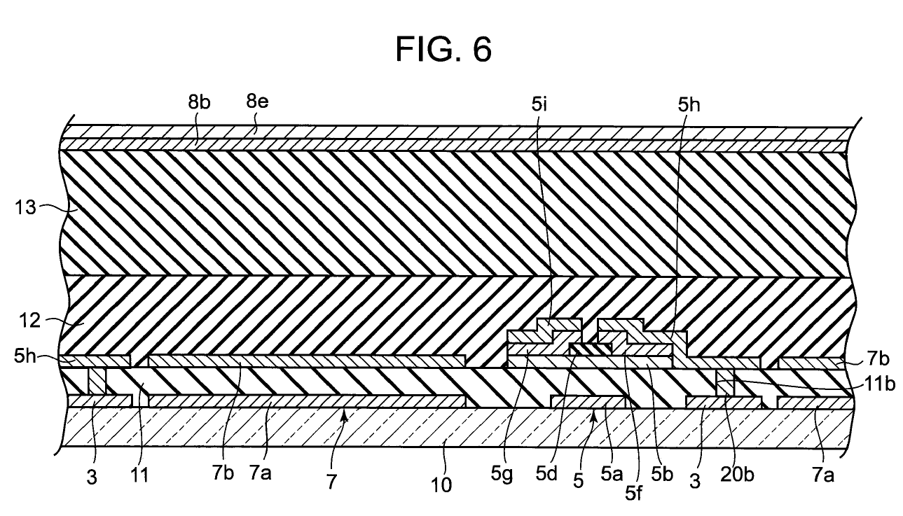

Next, a description will be made of the EL panel 1 and a circuit structure of the pixels P thereof by using FIG. 4 to FIG. 6. Here, FIG. 4 is a plan view equivalent to one pixel P of the EL panel 1, FIG. 5 is an arrow cross-sectional view of a plane along a line V-V of FIG. 4, and FIG. 6 is an arrow cross-sectional view of a plane along a line VI-VI of FIG. 4. Note that FIG. 4 mainly shows electrodes and wires.

As shown in FIG. 4, the switch transistor 5 and the drive transistor 6 are arrayed along the signal line 3, the capacitor 7 is disposed in the vicinity of the switch transistor 5, and the EL element 8 is disposed in the vicinity of the drive transistor 6. Moreover, between the scan line 2 and the voltage supply line 4 which correspond to the pixel, the switch transistor 5, the drive transistor 6, the capacitor 7 and the EL element 8 are arranged.

As shown in FIG. 4 to FIG. 6, a gate insulating film 11 is deposited on one surface of a substrate 10, and an underlying insulating film 12 is deposited on the switch transistor 5, the drive transistor 6 and the gate insulating film 11 arranged on the peripheries thereof. The signal line 3 is formed between the gate insulating film 11 and the substrate 10, and the scan line 2 and the voltage supply line 4 are formed between the gate insulating film 11 and the underlying insulating film 12.

Moreover, as shown in FIG. 4 and FIG. 6, the switch transistor 5 is a thin-film transistor with an inverted staggered structure. This switch transistor 5 includes a gate electrode 5a, a semiconductor film 5b, a channel protection film 5d, impurity semiconductor films 5f and 5g, a drain electrode 5h, a source electrode 5i and the like.

The gate electrode 5a is formed between the substrate 10 and the gate insulating film 11. The gate electrode 5a is composed of, for example, a Cr film, an Al film, a Cr/Al stacked film, an AlTi alloy film or an AlTiNd alloy film. Moreover, the gate insulating film 11 having insulating properties is deposited on the gate electrode 5a, and the gate electrode 5a is coated with the gate insulating film 11.

The gate insulating film 11 is composed of, for example, silicon nitride or silicon oxide. The intrinsic semiconductor film 5b is formed at a position that is on the gate insulating film 11 and corresponds to the gate electrode 5a, and the semiconductor film 5b is opposite to the gate electrode 5a while sandwiching the gate insulating film 11.

The semiconductor film 5b is composed of, for example, amorphous silicon or polysilicon, and a channel is formed in the semiconductor film 5b. Moreover, the channel protection film 5d having the insulating properties is formed on a center portion of the semiconductor film 5b. The channel protection film 5d is composed of, for example, the silicon nitride or the silicon oxide.

Moreover, on one of end portions of the semiconductor film 5b, the impurity semiconductor film 5f is formed so as to partially overlap the channel protection film 5d, and on the other end portion of the semiconductor film 5b, the impurity semiconductor film 5g is formed so as to partially overlap the channel protection film 5d. Then, the impurity semiconductor films 5f and 5g are formed on both end sides of the semiconductor film 5b so as to be spaced from each other. Note that, though the impurity semiconductor films 5f and 5g are n-type semiconductors, the impurity semiconductor films 5f and 5g is not limited to this and may be p-type semiconductors.

The drain electrode 5h is formed on the impurity semiconductor film 5f. The source electrode 5i is formed on the impurity semiconductor film 5g. The drain electrode 5h and the source electrode 5i are composed of, for example, Cr films, Al films, Cr/Al stacked films, AlTi alloy films or AlTiNd alloy films.

The underlying insulating film 12 having the insulating properties and serving as a protection film is deposited on the channel protection film 5d, the drain electrode 5h and the source electrode 5i, and the channel protection film 5d, the drain electrode 5h and the source electrode 5i are coated with the underlying insulating film 12. Then, the switch transistor 5 is covered with the underlying insulating film 12. The underlying insulating film 12 is composed of, for example, silicon nitride or silicon oxide having a thickness of 100 nm to 200 nm.

Moreover, as shown in FIG. 4 and FIG. 5, the drive transistor 6 is the thin-film transistor with the inverted staggered structure. The drive transistor 6 includes a gate electrode 6a, a semiconductor film 6b, a channel protection film 6d, impurity semiconductor films 6f and 6g, a drain electrode 6h, a source electrode 6i and the like.

The gate electrode 6a is composed of, for example, a Cr film, an Al film, a Cr/Al stacked film, an AlTi alloy film or an AlTiNd alloy film, and is formed between the substrate 10 and the gate insulating film 11 in a similar way to the gate electrode 5a. Then, the gate electrode 6a is coated with the gate insulating film 11 composed of, for example, the silicon nitride or the silicon oxide.

At a position that is on the gate insulating film 11 and corresponds to the gate electrode 6a, the semiconductor film 6b in which the channel is formed is formed of, for example, the amorphous silicon or the polysilicon. The semiconductor film 6b is opposite to the gate electrode 6a while sandwiching the gate insulating film 11 therebetween.

The channel protection film 6d having the insulating properties is formed on a center portion of the semiconductor film 6b. The channel protection film 6d is composed of, for example, the silicon nitride or the silicon oxide.

Moreover, on one of end portions of the semiconductor film 6b, the impurity semiconductor film 6f is formed so as to partially overlap the channel protection film 6d, and on the other end portion of the semiconductor film 6b, the impurity semiconductor film 6g is formed so as to partially overlap the channel protection film 6d. Then, the impurity semiconductor films 6f and 6g are formed on both end sides of the semiconductor film 6b so as to be spaced from each other. Note that, though the impurity semiconductor films 6f and 6g are n-type semiconductors, the impurity semiconductor films 6f and 6g is not limited to this and may be p-type semiconductors.

The drain electrode 6h is formed on the impurity semiconductor film 6f. The source electrode 6i is formed on the impurity semiconductor film 6g. The drain electrode 6h and the source electrode 6i are composed of, for example, Cr films, Al films, Cr/Al stacked films, AlTi alloy films or AlTiNd alloy films.

The underlying insulating film 12 having the insulating properties and serving as the protection film is deposited on the channel protection film 6d, the drain electrode 6h and the source electrode 6i, and the channel protection film 6d, the drain electrode 6h and the source electrode 6i are coated with the underlying insulating film 12. Then, the drive transistor 6 is covered with the underlying insulating film 12.

As shown in FIG. 4 and FIG. 6, the capacitor 7 includes a pair of electrodes 7a and 7b opposite to each other, and the gate insulating film 11 as a dielectric interposed therebetween. Then, one electrode 7a is formed between the substrate 10 and the gate insulating film 11, and the other electrode 7b is formed between the gate insulating film 11 and the underlying insulating film 12.

Note that the electrode 7a of the capacitor 7 is connected to the gate electrode 6a of the drive transistor 6 integrally and continuously therewith, and the electrode 7b of the capacitor 7 is connected to the source electrode 6i of the drive transistor 6 integrally and continuously therewith. Moreover, the drain electrode 6h of the drive transistor 6 continues integrally with the voltage supply line 4.

Note that the signal line 3, the electrode 7a of the capacitor 7, the gate electrode 5a of the switch transistor 5, and the gate electrode 6a of the drive transistor 6 are collectively formed by shaping a gate metal layer as a conductive film, which is deposited entirely on the substrate 10, by a photolithography method, an etching method and the like.

Moreover, the scan line 2, the voltage supply line 4, the electrode 7b of the capacitor 7, the drain electrode 5h and source electrode 5i of the switch transistor 5, and the drain electrode 6h and source electrode 6i of the drive transistor 6 are formed by shaping a source/drain metal layer as a conductive film, which is deposited entirely on the gate insulating film 11 and the like, by the photolithography method, the etching method and the like.

Moreover, in the gate insulating film 11, a contact hole 11a is formed in a region where the gate electrode 5a and the scan line 2 overlap each other, a contact hole 11b is formed in a region where the drain electrode 5h and the signal line 3 overlap each other, and a contact hole 11c is formed in a region where the gate electrode 6a and the source electrode 5i overlap each other. Contact plugs 20a to 20c are embedded in the contact holes 11a to 11c, respectively. The gate electrode 5a of the switch transistor 5 and the scan line 2 electrically conduct to each other by the contact plug 20a, the drain electrode 5h of the switch transistor 5 and the signal line 3 electrically conduct to each other by the contact plug 20b, and by the contact plug 20c, the source electrode 5i of the switch transistor 5 and the electrode 7a of the capacitor 7 electrically conduct to each other, and the source electrode 5i of the switch transistor 5 and the gate electrode 6a of the drive transistor 6 electrically conduct to each other. Without interposing the contact plugs 20a to 20c, the scan line 2 may directly contact the gate electrode 5a, the drain electrode 5h may directly contact the signal line 3, and the source electrode 5i may directly contact the gate electrode 6e.

The first electrode 8a is provided above the substrate 10 while interposing the gate insulating film 11, and is formed independently of each of the pixels P. In the case where the EL panel 1 is of a bottom emission type that emits light of the EL element 8 from the substrate 10, the first electrode 8a is a transparent electrode, and contains, for example, at least any of tin-doped indium oxide (ITO), zinc-doped indium oxide, indium oxide (In₂O₃), tin oxide (SnO₂), zinc oxide (ZnO) and cadmium-tin oxide (CTO). In the case where the EL panel 1 is of a top emission type that emits the light of the El element 8 through a second electrode 8e to be described later, the first electrode 8a may have a stack structure composed of a layer serving as the above-described transparent electrode, and of a light reflection layer such as an Al film and an Al alloy film, which is provided under the layer of the transparent electrode. At this time, the light reflection layer may be formed of the source/drain metal layer. Note that the first electrode 8a partially overlaps the source electrode 6i of the drive transistor 6, and the first electrode 8a and the source electrode 6i are connected to each other.

Then, as shown in FIG. 4 to FIG. 6, the underlying insulating film 12 is formed so as to cover the scan line 2, the signal line 3, the voltage supply line 4, the switch transistor 5, the drive transistor 6, a peripheral edge portion of the first electrode 8a, the electrode 7b of the capacitor 7, and the gate insulating film 11.

In the underlying insulating film 12, an opening portion 12a is formed so that a center portion of each first electrode 8a can be exposed. Therefore, the underlying insulating film 12 is formed in a grid shape when viewed from the above.

As shown in FIG. 4 and FIG. 5, the EL element 8 includes: the first electrode 8a as a pixel electrode, which serves as an anode; the hole injection layer 8b as a carrier transporting layer, which is formed on the first electrode 8a exposed from an inside of an opening portion 13a of the bank 13, and on a surface of the bank 13 on the periphery thereof; the functional layer 8c as a carrier transporting layer, which is formed on the hole injection layer 8b in the opening portion 13a of the bank 13; the light emitting layer 8d formed on the functional layer 8c; and the second electrode 8e as an opposite electrode, which serves as a cathode formed on the light emitting layer 8d. The second electrode 8e is a single electrode common to all the pixels P, and is formed continuously on all the pixels P.

The hole injection layer 8b is a layer composed of, for example, a transition metal oxide, and is a carrier injection layer for injecting holes from the first electrode 8a to the light emitting layer 8d. For the hole injection layer 8b, transition metal oxides such as molybdenum oxide, vanadium oxide, tungsten oxide and titanium oxide can be used. In particular, the molybdenum oxide is preferable.

The functional layer 8c is an interlayer (electron transportation suppressing layer) composed of, for example, a polyolefin material, and has a function to suppress electrons from moving from the light emitting layer 8d to the hole injection layer 8b side.

The light emitting layer 8d is a layer that contains an organic material emitting light of any of red (R), green (G) and blue (B) for each of the pixels P, is composed of, for example, a conjugate double bond polymer such as a polyfluorene light emitting material and a poly (phenylene vinylene) light emitting material, and emits light by recombining the electrons supplied from the second electrode 8e and the holes injected from the hole injection layer 8b. Therefore, the pixel P that emits the light of red (R), the pixel P that emits the light of green (G), and the pixel P that emits the light of blue (B) are different from one another in light emitting material of the light emitting layer 8d. A pattern of arranging the red (R), green (G) and blue (B) of the pixels P may be of a delta array, or may be a stripe pattern in which the pixels of the same colors are arrayed in the longitudinal direction.

In the case where the EL panel 1 is of the bottom emission type, the second electrode 8e may have a stacked structure of a low work function layer in which work functions of Mg, Ca, Ba, Li and the like are 4.0 eV or less, more preferably, 3.0 eV or less, and a thickness is 20 nm or less, and of a light reflection layer such as an Al film and an Al alloy film, which is provided on the low work function layer, and in which a thickness is 100 nm or more for the purpose of reducing sheet resistance. Moreover, in the case where the El panel 1 is of the top emission type, the second electrode 8e may have a stacked structure of the above-described low work function layer, and of a transparent conductive layer that is provided on the low work function layer and composed of, for example, the tin-doped indium oxide (ITO), the zinc-doped indium oxide, the indium oxide (In₂O₃), the tin oxide (SnO₂), the zinc oxide (ZnO), the cadmium-tin oxide (CTO) or the like.

The second electrode 8e is the electrode common to all the pixels P, and coats the bank 13 to be described later together with the light emitting layers 8d and the like.

The bank 13 is the partition formed on the underlying insulating film 12, and is composed of, for example, a resin material having the insulating properties, such as a photosensitive polyimide resin material. The bank 13 functions as the partition that prevents liquids formed in such a manner that materials serving as the functional layers 8c and the light emitting layers 8d are dissolved or dispersed into a solvent from flowing out to the adjacent pixels P.

Then, the light emitting layers 8d serving as light emitting spots are partitioned for each of the pixels P by the bank 13 and the underlying insulating film 12.

In each of the openings 13a of the bank 13, the hole injection layer 8b, the functional layer 8c and the light emitting layer 8d are stacked on the first electrode 8a.

For example, as shown in FIG. 5, the hole injection layer 8b is stacked on the first electrode 8a in the opening portion 13a of the back 13.

Then, on the hole injection layer 8b in each of the opening portions 13a, a compound film obtained by applying the liquid that contains the material serving as the functional layer 8c thereon, and heating the applied liquid together with the substrate 10, drying and depositing the liquid, is formed. The compound film thus formed is stacked as the functional layer 8c.

Moreover, on the functional layer 8c in each of the opening portions 13a, a compound film obtained by applying the liquid that contains the material serving as the light emitting layer 8d thereon, and heating the applied liquid together with the substrate 10, drying and depositing the liquid, is formed. The compound film thus formed is stacked as the light emitting layer 8d.

Note that the second electrode 8e is provided so as to coat the light emitting layer 8d and the bank 13 (refer to FIG. 5).

The EL panel 1 emits the light by being driven in the following manner.

ON voltages are sequentially applied to the scan lines 2 by the scan driver in a state where a voltage of a predetermined level is applied to all the voltage supply lines 4. Thereby, the switch transistors 5 connected to the scan lines 2 are sequentially selected.

When voltages of levels corresponding to gradations are applied to all the signal lines 3 by the data driver in case that the respective scan lines 2 are individually selected, the voltages of the levels corresponding to the gradations are applied to the gate electrodes 6a of the drive transistors 6 since the switch transistors 5 corresponding to the selected scan lines 2 are turned on.

In response to the voltages applied to the gate electrodes 6a of the drive transistors 6, potential differences between the gate electrodes 6a and source electrodes 6i of the drive transistors 6 are determined, drain-source currents flowing in the drive transistors 6 are determined, and each of the EL elements 8 emits the light with brightness corresponding to each of the drain-source currents.

Thereafter, the selection of the scan lines is released, the switch transistors 5 are turned off, and accordingly, charges which are in accordance with the voltages applied to the gate electrodes 6a of the drive transistors 6 are accumulated in the capacitors 7, and the potential differences between the gate electrodes 6a and source electrodes 6i of the drive transistors 6 are held.

Therefore, the drive transistors 6 continue to flow drain-source currents with the same current values as those at the time of the selection. Thereby, such light emission brightness of each of the EL elements 8 is maintained.

Next, a description will be made of a manufacturing method of the EL panel 1.

The gate metal layer is deposited on the substrate 10 by sputtering, and is patterned by the photolithography to form the signal lines 3, the electrodes 7a of the capacitors 7, the gate electrodes 5a of the switch transistors 5, and the gate electrodes 6a of the drive transistors 6.

Subsequently, the gate insulating film 11 such as the silicon nitride is deposited by plasma CVD.

Subsequently, a semiconductor layer made of the amorphous silicon or the like, which serves as the semiconductor films 5b and 6b, and an insulating layer made of the silicon nitride or the like, which serves as the channel protection films 5d and 6d, are deposited continuously. Thereafter, the channel protection films 5d and 6d are formed into patterns by the photolithography, and an impurity layer serving as the impurity semiconductor films 5f, 5g, 6f and 6g are deposited. Thereafter, the impurity layer and the semiconductor layer are patterned continuously by the photolithography, to form the impurity semiconductor films 5f, 5g, 6f and 6g and the semiconductor films 5b and 6b.

Then, by the photolithography, in the gate insulating film 11, contact holes (not shown) which open external connection terminals of the scan lines 2, which are for connecting the scan lines 2 to the scan driver located on one side of the EL panel 1; and the contact holes 11a to 11c, are formed. Subsequently, the contact plugs 20a to 20c are formed in the contact holes 11a to 11c. A forming step of the contact plugs may be omitted.

Subsequently, the source/drain metal layer that serves as the drain electrodes 5h and source electrodes 5i of the switch transistors 5 and as the drain electrodes 6h and source electrodes 6i of the drive transistors 6 is deposited and appropriately patterned. In such a way, the scan lines 2, the voltage supply lines 4, the electrodes 7b of the capacitors 7, the drain electrodes 5h and source electrodes 5i of the switch transistors 5, and the drain electrodes 6h and source electrodes 6i of the drive transistors 6 are formed. Thereafter, the transparent conductive film made of the ITO or the like is deposited and thereafter patterned to form the first electrodes 8a. In the case where the EL panel 1 is of the top emission type, the source/drain metal layer or other light reflective conductive films may be provided below the transparent conductive film.

Subsequently, an insulating film made of the silicon nitride or the like is formed by vapor deposition so as to cover the switch transistors 5, the drive transistors 6 and the like, and the insulating film is patterned by the photolithography to form the underlying insulating film 12 having the opening portions 12a to which the center portions of the first electrodes 8a are exposed. Together with the opening portions 12a, a plurality of the contact holes which individually open the external connection terminals (not shown) of the scan lines 2, external connection terminals of the signal lines 3 and external connection terminals of the voltage supply lines 4, which are for connecting the signal lines 3 and the voltage supply lines 4 to the data driver located on one side of the EL panel 1, are formed.

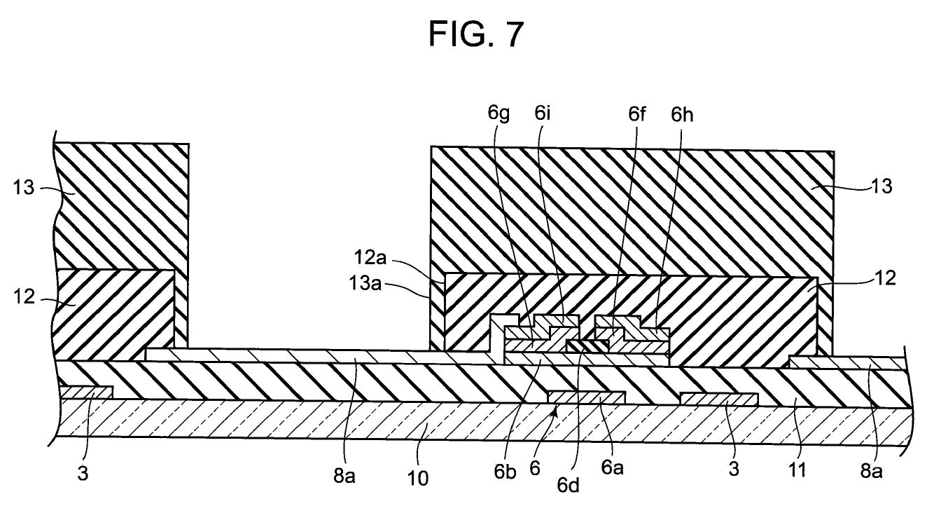

Subsequently, as shown in FIG. 7, the polyimide photosensitive resin material is deposited, and is thereafter exposed and developed to form the grid-like bank 13 having the opening portions 13a to which the first electrodes 8a are exposed.

Subsequently, oxygen plasma treatment is implemented for the bank 13 and the first electrodes 8a to remove a surface layer of the bank 13 so as to be cut away by a thickness of 50 nm or more and 1 μm or less, and to remove residual organic matter on the first electrodes 8a.

Note that a thickness of the bank 13 formed by the deposition is approximately 1.5 to 3.5 μm. Accordingly, even if the surface layer of the bank 13 is removed by approximately 1 μm, the function of the bank 13 that is the partition for preventing the liquids containing the materials serving as the functional layers 8c and the light emitting layers 8d from flowing out to the adjacent pixels P at the time when the liquids are applied thereon, is maintained.

Specifically, the bank 13 of which surface layer is cut away by carrying out the oxygen plasma treatment has a thickness of at least 0.5 μm.

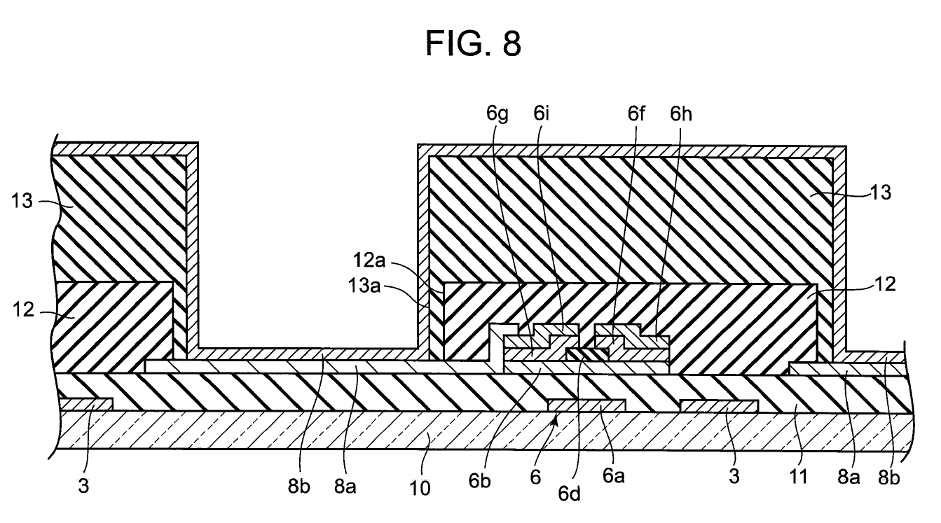

Subsequently, as shown in FIG. 8, a transition metal oxide layer composed of the molybdenum oxide is deposited by the sputtering, vacuum evaporation or the like to form the hole injection layer 8b on the first electrodes 8a.

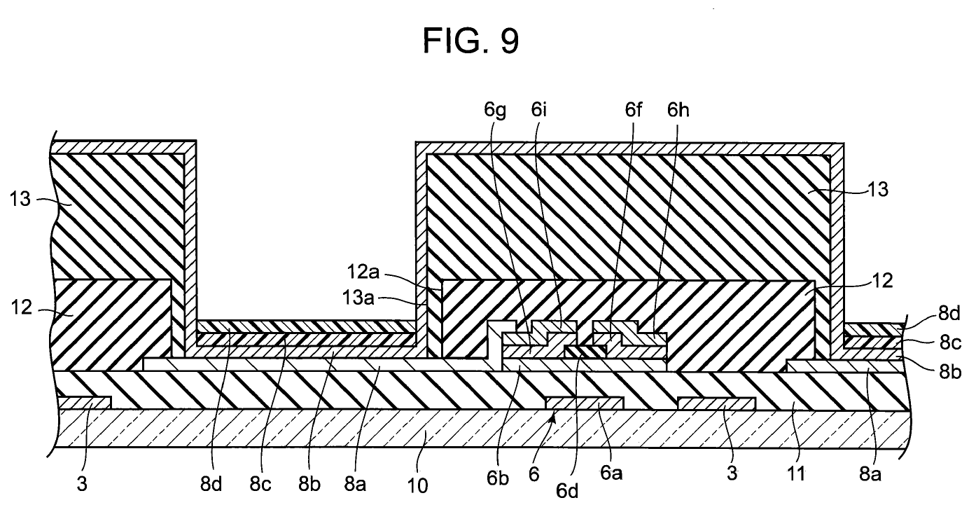

Subsequently, as shown in FIG. 9, a liquid in which an organic material composing the functional layers 8c is dissolved or dispersed into an organic solvent such as tetralin, tetramethylbenzene and mesitylene is applied on the hole injection layer 8b in the opening portions 13a of the bank 13 by an ink-jet method of ejecting a plurality of separate liquid droplets or a nozzle printing method of flowing out a continuous liquid flow, and is dried. Thereby, the functional layers 8c is formed on the hole injection layer 8b by the stacking.

Moreover, as shown in FIG. 9, a liquid in which an organic light emitting material composing the light emitting layers 8d is dissolved or dispersed into the organic solvent such as the tetralin, the tetramethylbenzene and the mesitylene is applied on the functional layers 8c in the opening portions 13a of the bank 13 by the ink-jet method or the nozzle printing method, and is dried. Thereby, the light emitting layers 8d are formed on the functional layers 8c by the stacking. Note that a structure in which the light emitting layers 8d are directly stacked on the hole injection layers 8b without providing the functional layers 8c, may be adopted.

Then, as shown in FIG. 5, the second electrode 8e that covers the light emitting layers 8d is deposited entirely on the bank 13 and the light emitting layers 8d. Thereby, the EL elements 8 are formed, and the EL panel 1 is manufactured.

In the above-described embodiment, in the structure, the opening portions 13a of the bank 13 are provided for each of the pixels P. The light emitting layers 8d and the functional layers 8c are provided independently of each of the opening portions 13a.

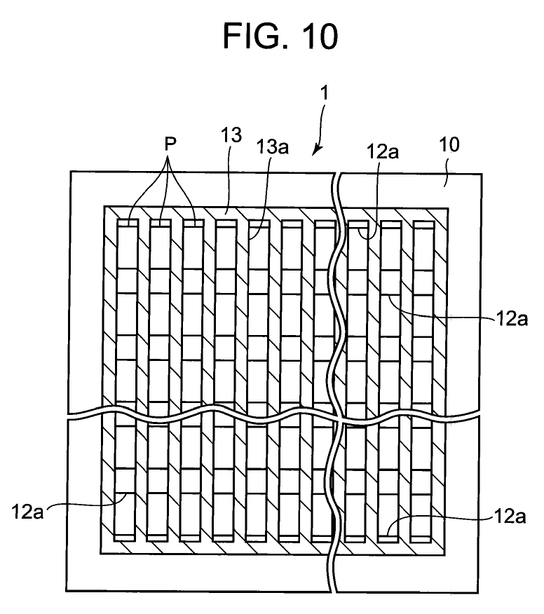

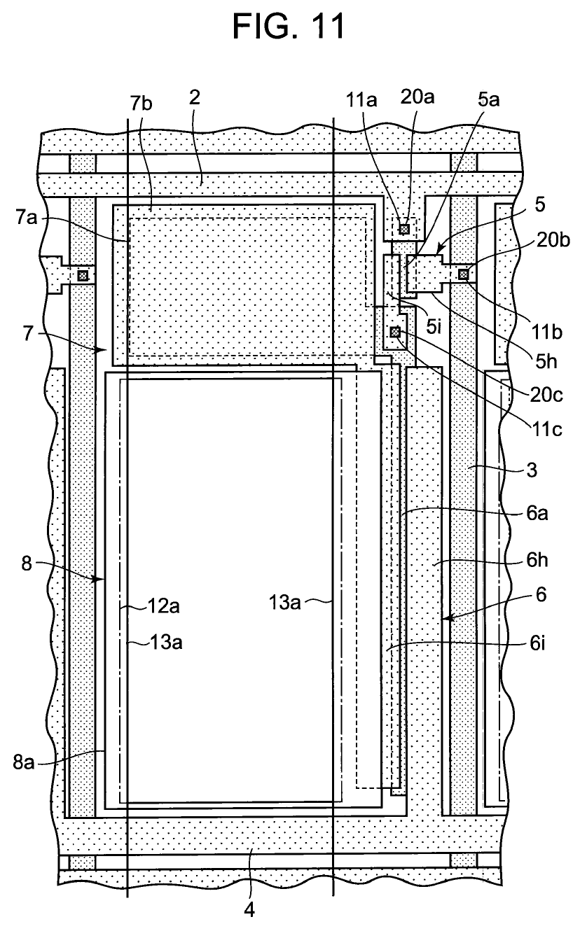

As opposed to this, as shown in FIG. 10, stripe-like opening portions 13a which collectively surround peripheries of a plurality of the pixels P along the column direction may be adopted. In this case, the number of opening portions 13a becomes the number corresponding to the number of signal lines 3. FIG. 11 is a plan view equivalent to one pixel P of the EL panel 1. In FIG. 11, the opening portion 13a is extended in the column direction in comparison with FIG. 4. Accordingly, on a part of the scan lines 2 and a part of the voltage lines 4, which are located in the column direction of the first electrodes 8a, the bank 13 is not provided though the underlying insulating film 12 is provided, respectively. Therefore, the liquid material serving as the functional layers 8c and the liquid material serving as the light emitting layers 8d continue to be flown in continuous liquid flows by the nozzle printing method so as to lie astride the plurality of pixels P in the column direction. Thereby, the functional layers 8c and the light emitting layers 8d can be collectively formed in the plurality of pixels P in one opening portion 13a. At this time, on the underlying insulating film 12 on which the opening portions 13a are not formed, the functional layers 8c and the light emitting layers 8d may be deposited; however, preferably, are not deposited. Specifically, also from a viewpoint of utilization efficiency of the materials, it is more preferable that the functional layers 8c and the light emitting layers 8d be partitioned in the column direction by the opening portions 12a, and be partitioned in the row direction by the opening portions 13a.

Moreover, in the above-described embodiment, as shown in FIG. 5, each of the opening portions 13a of the bank 13 is provided on inner side of the first electrode 8a than each of the opening portions 12a of the underlying insulating film 12.

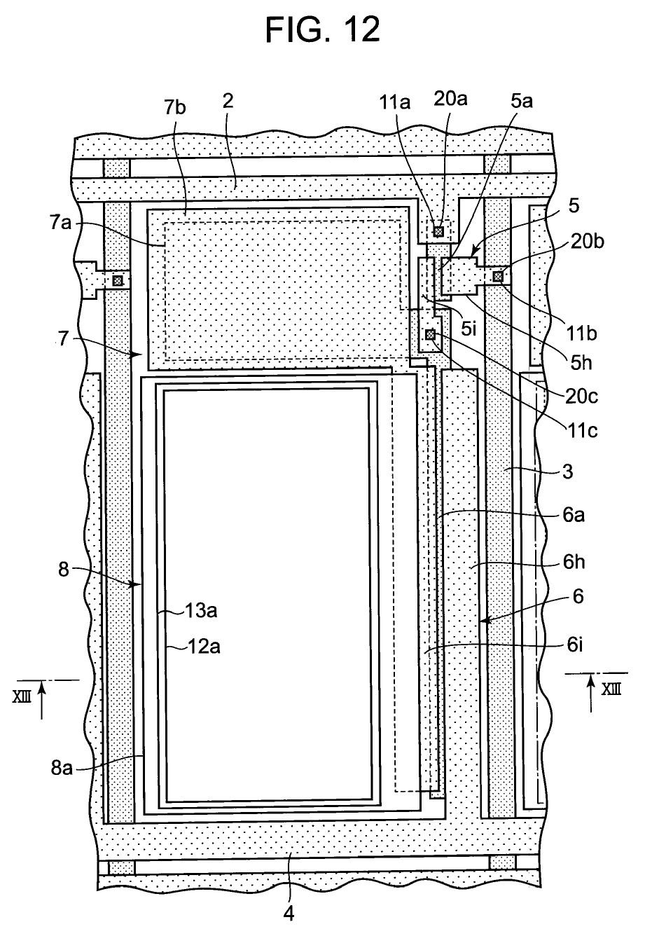

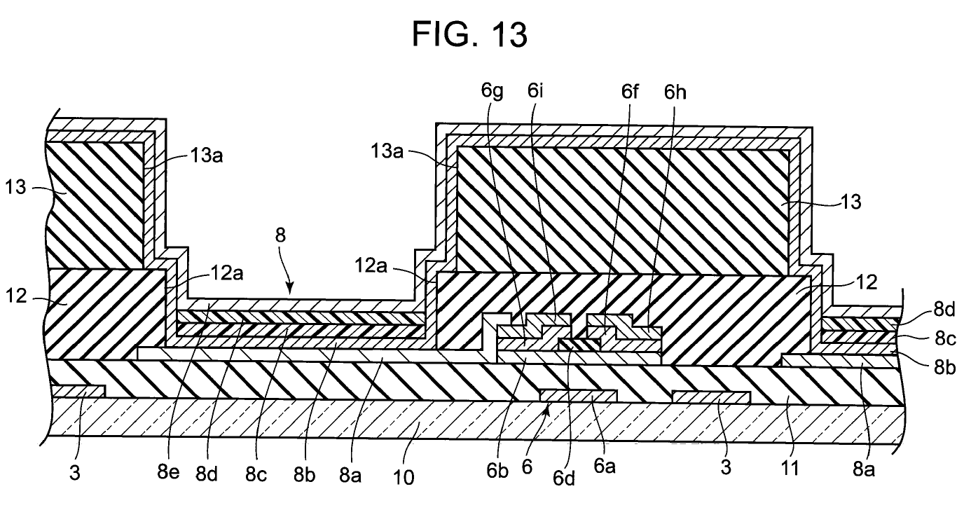

As opposed to this, as shown in FIG. 12 and FIG. 13, a structure in which each of the opening portions 12a of the underlying insulating film 12 is located on inner side of the first electrode 8a than each of the opening portions 13a of the bank 13 in the row direction and the column direction, may be adopted. In this case, in the EL panel 1, the opening portions 12a and the opening portions 13a are formed for each of the pixels P as shown in FIG. 1. Also in this case, it is preferable that the functional layers 8c and the light emitting layers 8d be formed in regions surrounded by the opening portions 12a of the underlying insulating film 12.

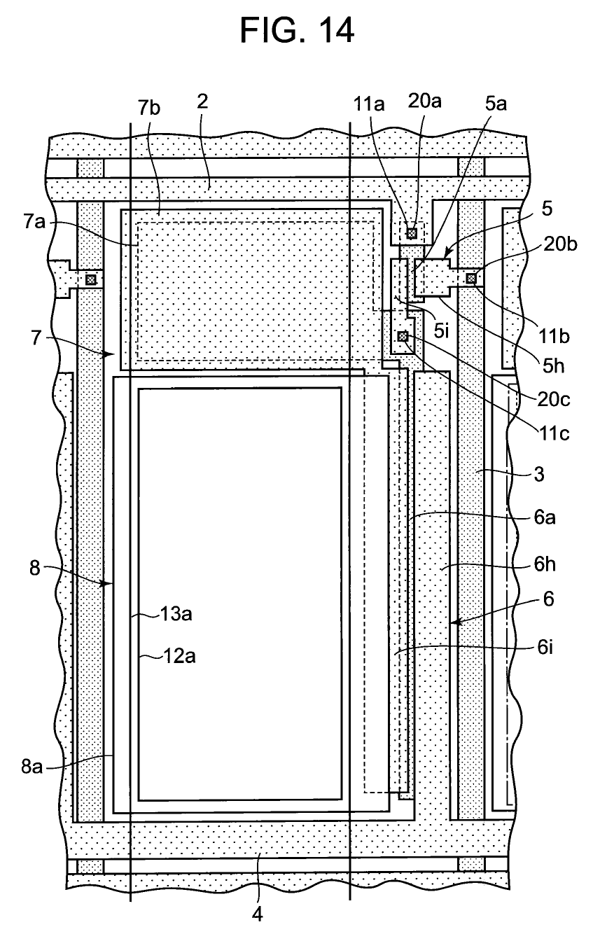

Moreover, as shown in FIG. 14, a structure in which each of the opening portions 12a of the underlying insulating film 12 is located on inner side of the first electrode 8a than each of the opening portions 13a of the bank 13 in the row direction and the column direction, may be adopted, and further, each of the opening portions 13a may have a stripe shape that collectively surrounds the peripheries of the plurality of pixels P along the column direction. In this case, the EL panel 1 forms the structure as shown in FIG. 10. The functional layer 8c and the light emitting layer 8d may be deposited on the underlying insulating film 12; however, preferably, is not deposited on the underlying insulating film 12.

Next, a description will be made of examples and comparative examples to confirm effects of the present invention.

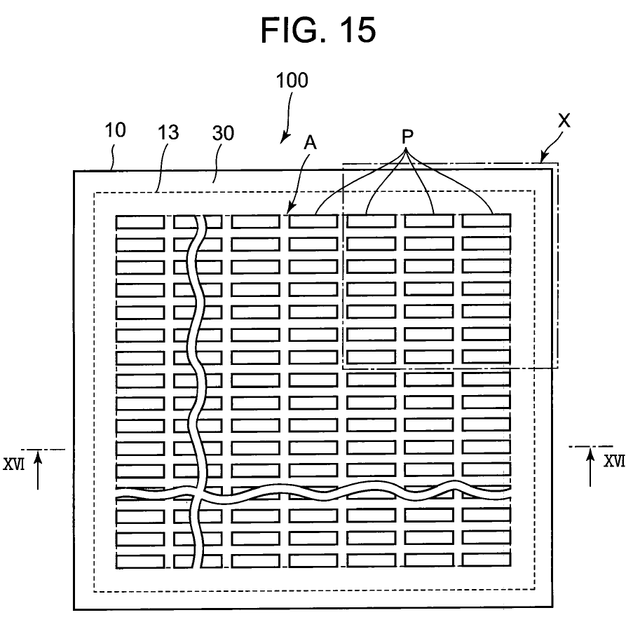

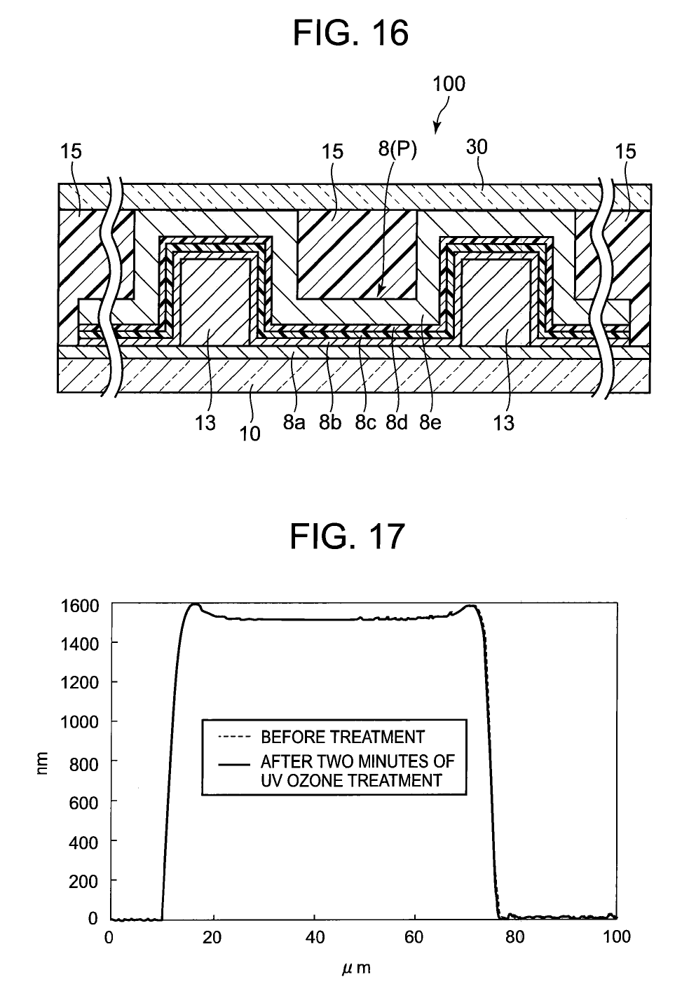

FIG. 15 is a plan view showing an EL panel 100 for use in a light emission test, and FIG. 16 is a cross-sectional view equivalent to one pixel P of the EL panel 100.

As shown in FIG. 15 and FIG. 16, the EL panel 100 for use in the light emission test includes: the first electrode 8a formed on an upper surface of the substrate 10; the bank 13 provided in the grid shape on an upper surface of the first electrode 8a; the hole injection layers 8b deposited on the first electrode 8a and the bank 13; the functional layers 8c deposited on the hole injection layers 8b; the light emitting layers 8d deposited on the functional layers 8c; the second electrodes 8e deposited on the light emitting layers 8d; a sealing substrate 30; a sealing material 15 filled between the substrate 10 and the sealing substrate 30 and between the second electrodes 8e and the sealing substrate 30; and the like.

The EL panel 100 has 588 pixels P, each of which is composed by being partitioned by the bank 13. Note that, in the EL panel 100, a range where the plurality of pixels P arrayed in the matrix form are present serves as a light emitting region (display region) A.

The substrate 10 and the sealing substrate 30 are glass substrates having light transmission properties.

The first electrode 8a is a transparent electrode composed of the ITO.

The bank 13 is composed of a positive-type photosensitive polyimide resin material, and “Photoneece DL-1000” made by Toray Industries, Inc. is used here.

The hole injection layers 8b are layers obtained by depositing the molybdenum oxide as the transition metal oxide layers.

The functional layers 8c are layers obtained by depositing a solution in which an interlayer material is dissolved into xylene, by the ink-jet method or the nozzle printing method.

The light emitting layers 8d are layers obtained by depositing a solution in which a polyfluorene green light emitting material is dissolved into the xylene, by the ink-jet method or the nozzle printing method.

The sealing material 15 is composed of a thermosetting resin material, and hermetically seals the respective layers (8a to 8e) composing the EL elements 8 between the substrate 10 and the sealing substrate 30.

Note that a power supply (not shown) that applies a predetermined voltage between the voltage supply lines 4 and the second electrodes 8e is connected to the EL panel 100.

The bank 13 provided on the first electrode 8a on the upper surface side of the substrate 10 was initially formed so as to have a thickness of approximately 1.5 μm. Then, the substrate 10 on which the bank 13 was formed was cleaned by using pure water, and was thereafter subjected to the oxygen plasma treatment that also served as surface cleaning of the first electrode 8a without performing UV ozone treatment. Thereby, the surface layer of the bank 13 was removed by a predetermined amount.

For the oxygen plasma treatment, a barrel-type asher “DES-106-254AEH” made by March Plasma Systems, Inc. was used, ashing under conditions where a vacuum degree was 0.6 [Torr], an RF output was 250 [W] and an O₂ flow rate was 60 [sccm] was implemented, and a treatment time thereof was adjusted appropriately (five minutes, seven minutes, ten minutes). Thereby, the surface layer of the bank 13 was removed by a predetermined amount (35 nm, 50 nm, 70 nm).

Then, after the oxygen plasma treatment, the molybdenum oxide as the hole injection layers 8b was deposited to 30 [nm] by an evaporation method.

Moreover, the EL panel 100 manufactured by sequentially depositing the functional layers 8c, the light emitting layers 8d and the second electrodes 8e and pasting thereon the sealing substrate 30 by the sealing material 15 was stored in a desiccator subjected to nitrogen substitution for seven days (7×24 h) under room temperature/room pressure. Thereafter, the light emission test of the EL panel 100 was implemented.

Note that, as subjects of the light emission test, three types of the EL panels 100 which are: an EL panel 100 including the bank 13 in which the surface layer was removed by 35 [nm] by implementing the oxygen plasma treatment for five minutes; an EL panel 100 including the bank 13 in which the surface layer was removed by 50 [nm] by implementing the oxygen plasma treatment for seven minutes; and an EL panel 100 including the bank 13 in which the surface layer was removed by 70 [nm] by implementing the oxygen plasma treatment for ten minutes, were prepared. Then, light emission states of the respective EL panels 100 were compared with one another, and it was confirmed whether the light emission states were good or not.

Moreover, for a comparison test, an EL panel 100 which was subjected to the UV ozone treatment for two minutes in place of the oxygen plasma treatment, and on which the molybdenum oxide as the hole injection layers 8b was deposited to 30 [nm] by the sputtering method after performing the surface cleaning for the first electrode 8a, was also prepared. In such a way, the light emission test was performed for totally four types of the EL panels 100.

Note that, for the UV ozone treatment, an UV cleaner made by Orc Manufacturing Co., Ltd. was used, and UV cleaning under conditions where a lamp output was 100 [W], the number of lamps (low pressure mercury lamps (VUV-100/A-5.3U); effective irradiation area: 400 [mm]) was seven, and an irradiation distance was 20 [mm] was implemented for the substrates 10 on which the banks 13 were formed.

A description will be made of surface shapes of the banks 13 in the EL panels 100 as the subjects of the light transmission test.

FIG. 17 shows data regarding the surface shape of the bank 13 subjected to the UV ozone treatment for two minutes. As shown in FIG. 17, in the UV ozone treatment for two minutes, the surface shape of the bank 13 is hardly changed before and after the treatment, and it is understood that the surface layer of the bank 13 is not cut away.

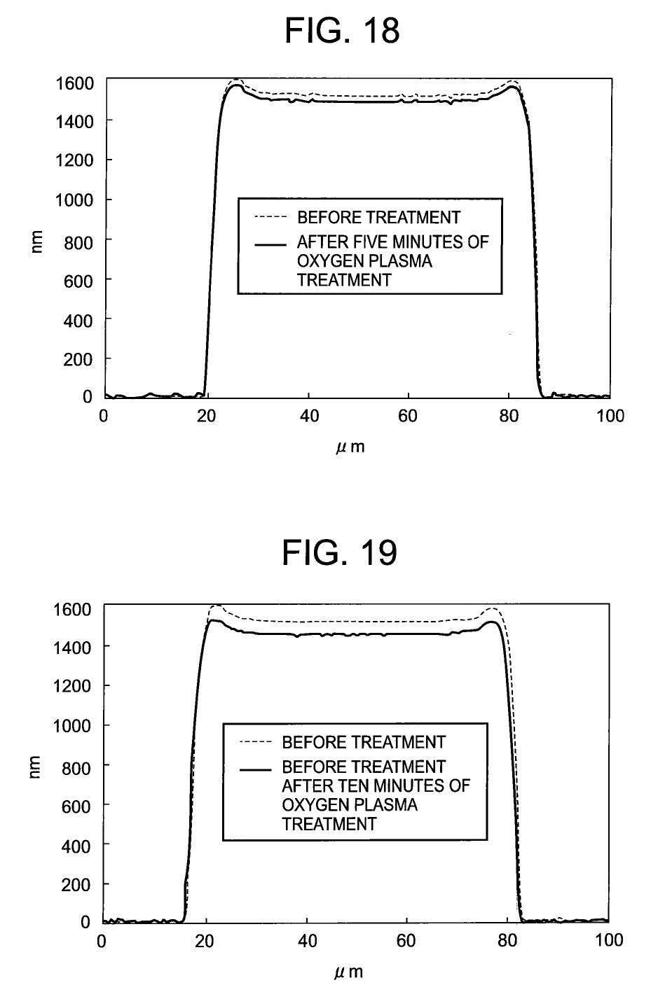

FIG. 18 shows data regarding the surface shape of the bank 13 subjected to the oxygen plasma treatment for five minutes, and FIG. 19 shows data regarding the surface shape of the bank 13 subjected to the oxygen plasma treatment for ten minutes. As shown in FIG. 18 and FIG. 19, it is understood that the surface of the bank 13 is cut away by approximately 35 [nm] by the oxygen plasma treatment for five minutes, and that the surface of the bank 13 is cut away by approximately 70 [nm] by the oxygen plasma treatment for ten minutes.

Note that, though not shown, the surface of the bank 13 is cut away by approximately 50 [nm] by the oxygen plasma treatment for seven minutes. This can be recognized also from the known fact that the treatment time of the oxygen plasma treatment and the cutaway amount of the surface layer of the bank 13 are in a proportional relationship.

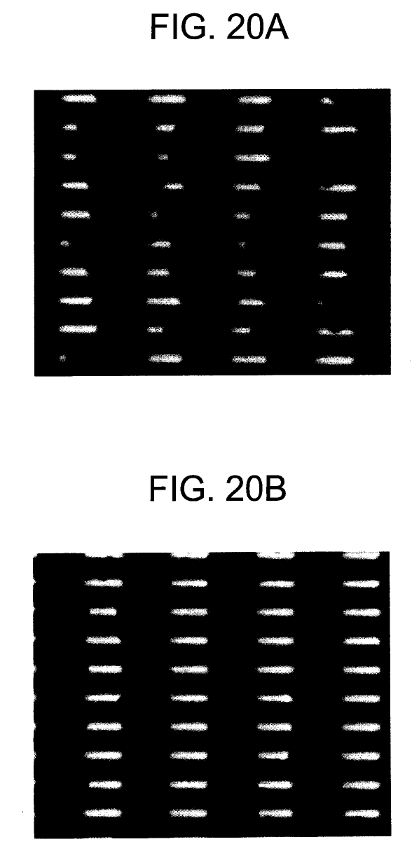

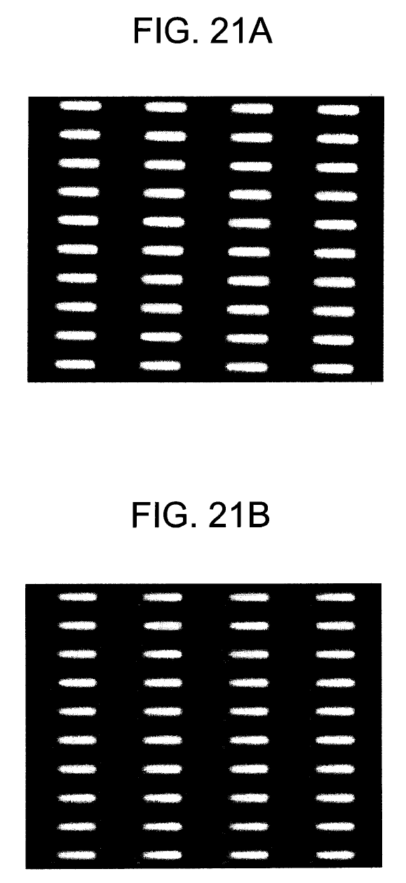

Results of the light emission test for the EL panels 100 are shown in FIG. 20A to FIG. 21B.

The EL panel 100 shown in FIG. 20A is of a comparative example where the EL panel 100 is subjected to the UV ozone treatment, in which the surface layer of the bank 13 is not cut away, and the EL panel 100 shown in FIG. 20B is of a comparative example where the surface layer of the bank 13 is removed by 35 nm.

Moreover, the EL panel 100 shown in FIG. 21A is of an example where the surface layer of the bank 13 is removed by 50 nm, and the EL panel 100 shown in FIG. 21B is of an example where the surface layer of the bank 13 is removed by 70 nm.

In a light emission image of the EL panel 100 shown in FIG. 20A, in the EL elements 8 (pixels P) in the light emitting region A, a large number of random regions where the EL elements 8 do not partially emit the light, so-called dark spots occur. Note that the dark spots occur in the pixels P located at random positions on the EL panel 100, and occur irregularly and indefinitely in random regions in the pixels P. Therefore, in this point, the dark spots are different from dark areas as non-light emitting regions which occur regularly and concentratedly on the pixels P on a peripheral edge of the EL panel 100. Moreover, the dark spots are circular, and a diameter of circles as the dark spots is increased with time.

In a light emission image of the EL panel 100, which is shown in FIG. 20B, the dark spots in which the EL elements 8 do not partially emit the light occur though a ratio thereof is small.

As opposed to this, in light emission images of the EL panels 100, which are shown in FIG. 21A and FIG. 21B, the dark spots do not occur, and it is understood that all the EL elements 8 emit the light uniformly and satisfactorily over the entire regions of the pixels P thereof.

Specifically, it is confirmed that the dark spots do not occur in the EL panels 100 in each of which the surface layer of the bank 13 is removed by 50 nm or more.

From the above results, the dark spots do not occur in such an EL panel 100 in which the surface layer of the bank 13 is removed by 50 nm or more by the oxygen plasma treatment prior to forming the hole injection layers 8b by depositing the molybdenum oxide layer. Accordingly, it can be said that the above EL panel 100 is a light emitting device excellent in light emission characteristics.

Moreover, it can be said that the manufacturing method of the light emitting device including the step of depositing the hole injection layers 8b composed of the molybdenum oxide after the surface layer of the bank 13 composed of the polyimide resin material is removed by the oxygen plasma treatment by 50 nm or more is a technology that makes it possible to manufacture the EL panel 100 (EL panel 1) excellent in light emission characteristics.

The reason why the EL panel 100 in which the surface layer of the bank 13 is removed by 50 nm or more by the oxygen plasma treatment as described above exhibits the excellent light transmission characteristics is not clarified. However, the reason can be assumed and interpreted in the following way. Specifically, if it is assumed that a component that inhibits hole injection properties of the molybdenum oxide is contained in the surface layer of the bank 13, then such an inhibition component and an inhibition cause are eliminated by removing the surface layer of the bank 13 by 50 nm or more. Therefore, the light emission characteristics are enhanced. Note that, in the case of forming the hole injection layers 8b by using a PEDOT/PSS aqueous solution as a fluid dispersion obtained by dispersing polyethylenedioxythiophene (PEDOT) and polystyrene sulfonic acid (PSS) as a dopant into an aqueous solvent, the dark spots were not reduced so significantly as in the case of using the molybdenum oxide even if the oxygen plasma treatment was performed in a similar way.

By using the EL panels 100 which do not include the switch transistors 5 and the drive transistors 6, the light emission characteristics of the above EL panel 100 for the light emission test were confirmed in the above-described respective example. However, whether these transistors are present or not does not affect the results of the light emission test since this test is a comparison test for the cutaway amounts of the bank 13. Specifically, it is a matter of course that similar test results can be obtained even in the case of adjusting the cutaway amount of the banks 13 in the EL panels 1 including the switch transistors 5 and the drive transistors 6.

Here, it is possible to manufacture the EL panels 100 which do not include the transistors more easily and quickly at lower cost. Accordingly, the light emission test using the above EL panels 100 was performed in terms of merits in repeating the test with the variety of conditions as such a confirmation test of the light emission characteristics.

Next, a description will be made of other effects of the present invention.

FIG. 10 is a plan view showing the EL panel 100 for use in the light emission test, and FIG. 11 is a cross-sectional view equivalent to one pixel P of the EL panel 100.

As shown in FIG. 10 and FIG. 11, the EL panel 100 for use in the light emission test includes: the first electrode 8a formed on the upper surface of the substrate 10; the bank 13 provided in the grid shape on the upper surface of the first electrode 8a; the hole injection layers 8b deposited on the first electrode 8a and the bank 13; the functional layers 8c deposited on the hole injection layers 8b; the light emitting layers 8d deposited on the functional layers 8c; the second electrodes 8e deposited on the light emitting layers 8d; the sealing substrate 30; the sealing material 15 filled between the substrate 10 and the sealing substrate 30 and between the second electrodes 8e and the sealing substrate 30; and the like.

The EL panel 100 has 588 pixels P, each of which is composed by being partitioned by the bank 13. Note that, in the EL panel 100, the range where the plurality of pixels P arrayed in the matrix form are present serves as the light emitting region (display region) A.

The substrate 10 and the sealing substrate 30 are the glass substrates having the light transmission properties.

The first electrode 8a is the transparent electrode composed of the ITO.

The bank 13 is composed of the positive-type photosensitive polyimide resin material, and “Photoneece DL-1000” made by Toray Industries, Inc. is used here.

The hole injection layers 8b are the layers obtained by depositing the molybdenum oxide as the transition metal oxide layers.

The functional layers 8c are the layers obtained by depositing the solution in which the interlayer material is dissolved into the xylene, by the ink-jet method or the nozzle printing method.

The light emitting layers 8d are the layers obtained by depositing the solution in which the polyfluorene green light emitting material is dissolved into the xylene, by the ink-jet method or the nozzle printing method.

The sealing material 15 is composed of the thermosetting resin material, and hermetically seals the respective layers (8a to 8e) composing the EL elements 8 between the substrate 10 and the sealing substrate 30.

Note that the power supply (not shown) that applies the predetermined voltage between the voltage supply lines 4 and the second electrodes 8e is connected to the EL panel 100.

The bank 13 provided on the first electrode 8a on the upper surface side of the substrate 10 was initially formed so as to have the thickness of approximately 1.5 μm. Then, the substrate 10 on which the bank 13 was formed was cleaned by using the pure water, and was thereafter subjected to the oxygen plasma treatment that also served as the surface cleaning of the first electrode 8a without performing the UV ozone treatment. Thereby, the surface layer of the bank 13 was removed by the predetermined amount.

For the oxygen plasma treatment, an asher “OPM-SQ1000E” made by Tokyo Ohka Kogyo Co., Ltd. was used, ashing under conditions where the vacuum degree was 0.6 [Torr], the RF output was 300 [W], the O₂ flow rate was 800 [sccm] and a substrate temperature was 45 [° C.] was implemented, and the treatment time thereof was adjusted appropriately. Thereby, the surface layer of the bank 13 was removed by a predetermined amount (50 nm, 70 nm, 90 nm, 110 nm).

Then, after the oxygen plasma treatment, the molybdenum oxide as the hole injection layers 8b was deposited to 30 [nm] by the evaporation method.

Moreover, the EL panel 100 manufactured by sequentially depositing the functional layers 8c, the light emitting layers 8d and the second electrodes 8e and pasting thereon the sealing substrate 30 by the sealing material 15 was stored in the desiccator subjected to the nitrogen substitution for seven days (7×24 h) under the room temperature/room pressure. Thereafter, the light emission test of the EL panel 100 was implemented.

Note that, as the subjects of the light emission test, four types of the EL panels 100 which are: an EL panel 100 including the bank 13 in which the surface layer was removed by 50 [nm]; an EL panel 100 including the bank 13 in which the surface layer was removed by 70 [nm]; an EL panel 100 including the bank 13 in which the surface layer was removed by 90 [nm]; and an EL panel 100 including the bank 13 in which the surface layer was removed by 110 [nm], were prepared. Then, light emission states of the respective EL panels 100 were compared with one another, and it was confirmed whether the light emission states were good or not.

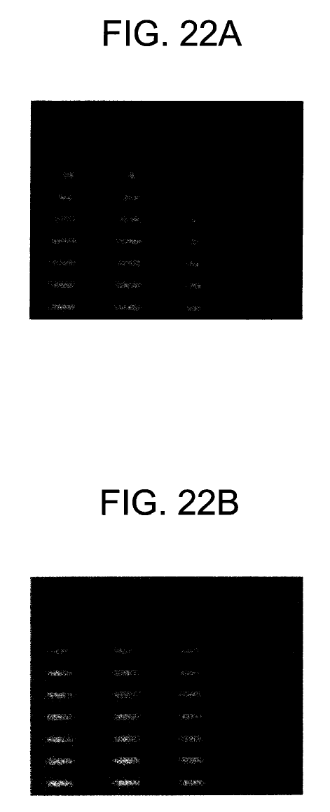

Results of the light emission test for the EL panels 100 are shown in FIG. 22A to FIG. 24B.

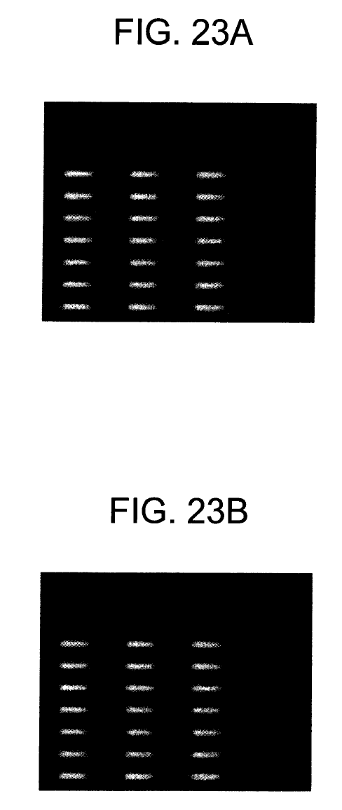

Regions of the EL panels 100, which are shown in FIG. 22A, FIG. 22B, FIG. 23A and FIG. 23B, are a portion X of a peripheral edge region in the EL panel 100 of FIG. 15.

The EL panel 100 shown in FIG. 22A is of an example where the surface layer of the bank 13 is removed by 50 nm, and the EL panel 100 shown in FIG. 22B is of an example where the surface layer of the bank 13 is removed by 70 nm.

Moreover, the EL panel 100 shown in FIG. 23A is of an example where the surface layer of the bank 13 is removed by 90 nm, and the EL panel 100 shown in FIG. 23B is of an example where the surface layer of the bank 13 is removed by 110 nm.

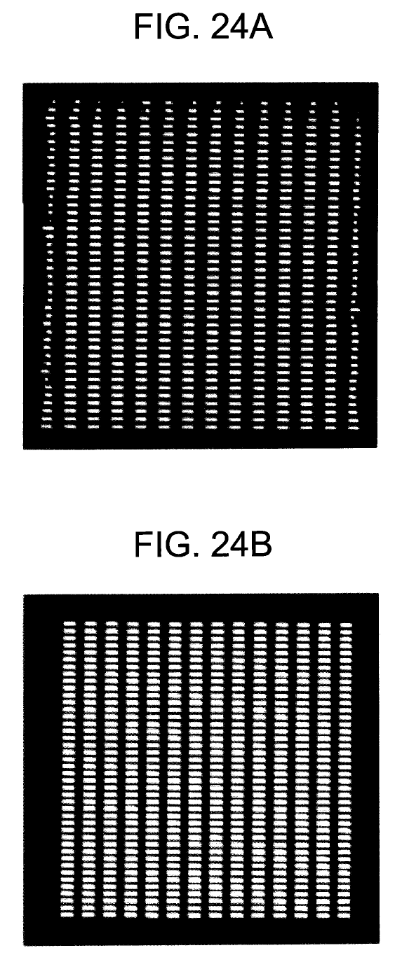

FIG. 24A shows an entire region of the EL panel 100 of the example where the surface layer of the bank 13 is removed by 50 nm, and FIG. 24B shows an entire region of the EL panel 100 of the example where the surface layer of the bank 13 is removed by 110 nm.

As shown in FIG. 24A, non-light emitting regions concentrate on the peripheral edges of the EL panel 100, and these are dark areas which grow with time from the pixels P on the peripheral edge side toward the inside pixels P. The dark areas are different from the spot-like dark spots in which the random spots of the pixels P at the random positions do not emit the light.

In a light emission image of the EL panel 100, which is shown in FIG. 22A, the dark areas in which the EL elements 8 do not partially emit the light occur in the EL elements 8 (pixels P) on the end portion side of the light emitting region A.

In a light emission image of the EL panel 100, which is shown in FIG. 22B, the dark areas in which the EL elements 8 do not partially emit the light occur though a ratio thereof is smaller than that of the EL panel 100 in which the surface layer of the bank 13 is removed by 50 nm.

As opposed to this, in light emission images of the EL panels 100, which are shown in FIG. 23A and FIG. 23B, the dark areas do not occur, and it is understood that all the EL elements 8 emit the light uniformly and satisfactorily over the entire regions of the pixels P thereof.

Specifically, it is confirmed that the dark areas do not occur in the EL panels 100 in each of which the surface layer of the bank 13 is removed by 90 nm or more.

From the above results, the dark areas do not occur in such an EL panel 100 in which the surface layer of the bank 13 is removed by 90 nm or more by the oxygen plasma treatment prior to forming the hole injection layers 8b by depositing the molybdenum oxide layer. Accordingly, it can be said that the above EL panel 100 is a light emitting device excellent in light emission characteristics.

Moreover, it can be said that the manufacturing method of the light emitting device including the step of depositing the hole injection layers 8b composed of the molybdenum oxide after the surface layer of the bank 13 composed of the polyimide resin material is removed by the oxygen plasma treatment by 90 nm or more is a technology that makes it possible to manufacture the EL panel 100 (EL panel 1) excellent in light emission characteristics.

The reason why the EL panel 100 in which the surface layer of the bank 13 is removed by 90 nm or more by the oxygen plasma treatment as described above exhibits the excellent light transmission characteristics is not clarified. However, the reason can be assumed and interpreted in the following way. Specifically, if it is assumed that the component that inhibits the hole injection properties of the molybdenum oxide is contained in the surface layer of the bank 13, and in particular, in the surface layer on the end portion side of the light emitting region A, then such an inhibition component and an inhibition cause are eliminated by removing the surface layer of the bank 13 by 90 nm or more. Therefore, the light emission characteristics are enhanced. Note that, in the case of forming the hole injection layers 8b by using the PEDOT/PSS aqueous solution as the fluid dispersion obtained by dispersing the polyethylenedioxythiophene (PEDOT) and the polystyrene sulfonic acid (PSS) as the dopant into the aqueous solvent, the dark areas were not reduced so significantly as in the case of using the molybdenum oxide even if the oxygen plasma treatment was performed in a similar way.

By using the EL panels 100 which do not include the switch transistors 5 and the drive transistors 6, the light emission characteristics of the above EL panel 100 for the light emission test were confirmed in the above-described respective example. However, whether these transistors are present or not does not affect the results of the light emission test since this test is a comparison test for the cutaway amounts of the bank 13. Specifically, it is a matter of course that similar test results can be obtained even in the case of adjusting the cutaway amount of the banks 13 in the EL panels 1 including the switch transistors 5 and the drive transistors 6.

Here, it is possible to manufacture the EL panels 100 which do not include the transistors more easily and quickly at lower cost. Accordingly, the light emission test using the above EL panels 100 was performed in terms of merits in repeating the test with the variety of conditions as such a confirmation test of the light emission characteristics.

Moreover, though the sealing substrate 30 is not arranged on the EL panel 1 in each of the above-described embodiments, the present invention is not limited to this. A construction in which the sealing substrate 30 is attached to the upper surface side of the second electrodes 8e in the EL panel 1 while interposing the sealing material 15 therebetween, and the EL elements 8 and the like are sandwiched between the sealing substrate 30 and the substrate 10, may be adopted.

Moreover, though the etching treatment was performed by the oxygen plasma in each of the above-described embodiments, similar effects can be obtained even if the etching is performed to a similar extent by CF₄ plasma treatment.

Furthermore, though the description has been made of each of the above embodiments by taking as an example the case where the light emitting device is applied to the EL panel as a display device, the present invention is not limited to this. The present invention may be applied to an exposure device, an optical addressing device, an illumination device, and the like.

It is a matter of course that, besides the above, specific detailed structures and the like can be also appropriately modified.

The entire disclosure of Japanese Patent Application Nos. 2008-163941 and 2008-163950, filed on Jun. 24, 2008, including specifications, claims, drawings, and summaries are incorporated herein by reference in their entirety.

Although the variety of typical embodiments have been shown and described, the present invention is not limited to the above-described embodiments. Hence, the scope of the present invention is limited only by the following claims.

What is claimed is:

1. A manufacturing method of a light emitting device in which at least one carrier transporting layer is interposed between a first electrode and a second electrode, the manufacturing method comprising:
removing a surface layer of a partition that surrounds a periphery of at least one side of the first electrode by a thickness of 50 nm or more; and
forming the carrier transporting layer on the first electrode, the carrier transporting layer being in contact with the partition and containing a transition metal oxide.

2. The manufacturing method of the light emitting device according to claim 1, wherein the partition contains a polyimide resin material.

3. The manufacturing method of the light emitting device according to claim 1, wherein the transition metal oxide contains molybdenum oxide.

4. The manufacturing method of the light emitting device according to claim 1, wherein the surface layer of the partition is removed by the thickness of 50 nm to 1 μm.

5. The manufacturing method of the light emitting device according to claim 1, wherein the surface layer of the partition is removed by the thickness of 90 nm to 1 μm.

6. The manufacturing method of the light emitting device according to claim 1, wherein the surface layer of the partition is removed by plasma treatment.

7. The manufacturing method of the light emitting device according to claim 1, wherein the surface layer of the partition is removed by oxygen plasma treatment.

8. The light emitting device which is manufactured by the manufacturing method of the light emitting device according to claim 1.

9. A light emitting device comprising:
a first electrode;
a second electrode;
at least one carrier transporting layer which is interposed between the first electrode and the second electrode;
a partition for surrounding a periphery of at least one side of the first electrode,
wherein a surface layer of the partition is removed by a thickness of 50 nm or more from a thickness of the surface layer at a time when the surface layer is deposited, and
the carrier transporting layer contains a transition metal oxide, is in contact with the partition, and is formed on the first electrode.

10. The light emitting device according to claim 9, wherein the partition has a thickness of at least 0.5 μm.

11. The light emitting device according to claim 9, wherein the partition contains a polyimide resin material.

12. The light emitting device according to claim 9, wherein the transition metal oxide contains molybdenum oxide.

13. The light emitting device according to claim 9, wherein the surface layer of the partition is removed by the thickness of 50 nm to 1 μm.

14. The light emitting device according to claim 9, wherein the surface layer of the partition is removed by the thickness of 90 nm to 1 μm.

15. The light emitting device according to claim 9, wherein an underlying insulating film is formed under the partition.

16. The light emitting device according to claim 15, wherein one side of an opening portion of the partition is provided on inner side of the first electrode than one side of an opening portion of the underlying insulating film.

17. The light emitting device according to claim 15, wherein one side of an opening portion of the underlying insulating film is provided on inner side of the first electrode than one side of an opening portion of the partition.

18. The light emitting device according to claim 15, wherein a transistor is formed under the underlying insulating film.

19. The light emitting device according to claim 18, wherein a capacitor using a gate insulating film of the transistor as a dielectric is provided.
